(19) United States
(12) Patent Application Publication
(10) Pub. No.: US 2008/0153280 A1
(43) Pub. Date: Jun. 26, 2008

(54) REACTIVE SPUTTER DEPOSITION OF A TRANSPARENT CONDUCTIVE FILM

(75) Inventors: Yanping Li, Mountain View, CA (US); Yan Ye, Saratoga, CA (US); Yong-Kee Chae, Pleasanton, CA (US); Tae Kyung Won, San Jose, CA (US); Ankur Kadam, Santa Clara, CA (US); Shuran Sheng, Sunnyvale, CA (US); Liwei Li, Sunnyvale, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 11/614,461

(22) Filed: Dec. 21, 2006

(51) Int. Cl. H01L 21/44

(52) U.S. Cl. 438/608

(57) ABSTRACT

Methods for sputter depositing a transparent conductive oxide (TCO) layer are provided in the present invention. The transparent conductive oxide layer may be utilized as a back reflector in a photovoltaic device. In one embodiment, the method includes providing a substrate in a processing chamber, forming a first portion of a transparent conductive oxide layer on the substrate by a first sputter deposition step, and forming a second portion of the transparent conductive oxide layer by a second sputter deposition step.

### BACKGROUND OF THE DISCLOSURE

1. Field of the Invention

The present invention relates to methods and apparatus for depositing a transparent conductive film, more specifically, for reactively sputtering depositing a transparent conductive film for photovoltaic devices.

2. Description of the Background Art

Photovoltaic (PV) devices or solar cells are devices which convert sunlight into direct current (DC) electrical power. PV or solar cells typically have one or more p-n junctions. Each junction comprises two different regions within a semiconductor material where one side is denoted as the p-type region and the other as the n-type region. When the p-n junction of the PV cell is exposed to sunlight (consisting of energy from photons), the sunlight is directly converted to electricity through the PV effect. PV solar cells generate a specific amount of electric power and cells are tiled into modules sized to deliver the desired amount of system power. PV modules are created by connecting a number of PV solar cells and are then joined into panels with specific frames and connectors.

Several types of PV devices including microcrystalline silicon film (μc-Si), amorphous silicon film (a-Si), polycrystalline silicon film (poly-Si) and the like are being utilized to form PV devices. A transparent conductive film or a transparent conductive oxide (TCO) film is often used as a top surface electrode, often referred as back reflector, disposed on the top of the PV solar cells. The transparent conductive oxide (TCO) film must have high optical transmittance in the visible or higher wavelength region to facilitate transmitting sunlight into the solar cells without adversely absorbing or reflecting light energy. Also, low contact resistance and high electrical conductivity of the transparent conductive oxide (TCO) film are desired to provide high photoelectric conversion efficiency and electricity collection. Certain degree of textured or rough surface of the transparent conductive oxide (TCO) layer is also desired to assist sunlight trapping in the films by promoting light scattering. Overly high impurities or contaminant of the transparent conductive oxide (TCO) film often result in high contact resistance at the interface of the TCO film and adjacent films, thereby reducing carrier mobility within the PV cells. Furthermore, insufficient transparency of the TCO film may adversely reflect light back to the environment, resulting in less sunlight entering the PV cells and a reduction in the photoelectric conversion efficiency.

Therefore, there is a need for an improved method for depositing a transparent conductive oxide film for PV cells.

### SUMMARY OF THE INVENTION

Methods for sputter deposition of a transparent conductive oxide (TCO) layer suitable for use in PV cells are provided in the present invention. The deposition methods provide a TCO layer having high transparency without adversely affecting the overall TCO layer conductivity. In one embodiment, a method for sputter deposition includes providing a substrate in a processing chamber, forming a first portion of a transparent conductive oxide layer on the substrate by a first sputter deposition step, and forming a second portion of the transparent conductive oxide layer by a second sputter deposition step.

In another embodiment, a method for sputter deposition of a transparent conductive oxide layer includes providing a substrate in a processing chamber, supplying a gas mixture into the processing chamber, sputtering source material from a target disposed in the processing chamber, adjusting a flow rate of the gas mixture supplied to the processing chamber during sputtering, and forming a transparent conductive oxide layer on the substrate.

In yet another embodiment, a method for sputter deposition of a transparent conductive oxide layer includes providing a substrate in a processing chamber, supplying a first gas mixture into the processing chamber, sputtering source material from a target disposed in the processing chamber, reacting the sputtered source material with the first gas mixture to form a first portion of a transparent conductive oxide layer on the substrate, supplying a second gas mixture into the processing chamber and reacting with the sputtered source material, and forming a second portion of the transparent conductive oxide layer on the substrate.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a schematic cross-sectional view of one embodiment of a process chamber in accordance with the invention;

FIG. 2 depicts an exemplary cross sectional view of a crystalline silicon-based thin film PV solar cell in accordance with one embodiment of the present invention;

FIG. 3 depicts a process flow diagram for depositing a TCO layer in accordance with one embodiment of the present invention;

FIG. 4 depicts an exemplary cross sectional view of a tandem type PV solar cell in accordance with one embodiment of the present invention; and

FIG. 5 depicts an exemplary cross sectional view of a triple junction PV solar cell in accordance with one embodiment of the present invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides methods for sputter depositing a TCO layer suitable for use in the fabrication of solar cells. In one embodiment, the TCO layer is sputter deposited by supplying different gas mixtures and/or different gas flow rates during sputtering, thereby tuning film properties to meet different and specific process requirements. In another embodiment, the TCO layer is sputter deposited as a back reflector in a solar cell unit by supplying different oxygen gas flow rate during sputtering, thereby tuning film properties to meet different and specific process requirements. In yet another embodiment, the TCO layer is sputter deposited as a back reflector in a solar cell unit by supplying different oxygen gas flow rate during a first and a second sputtering at a desired temperature, thereby tuning film properties to meet different and specific process requirements.

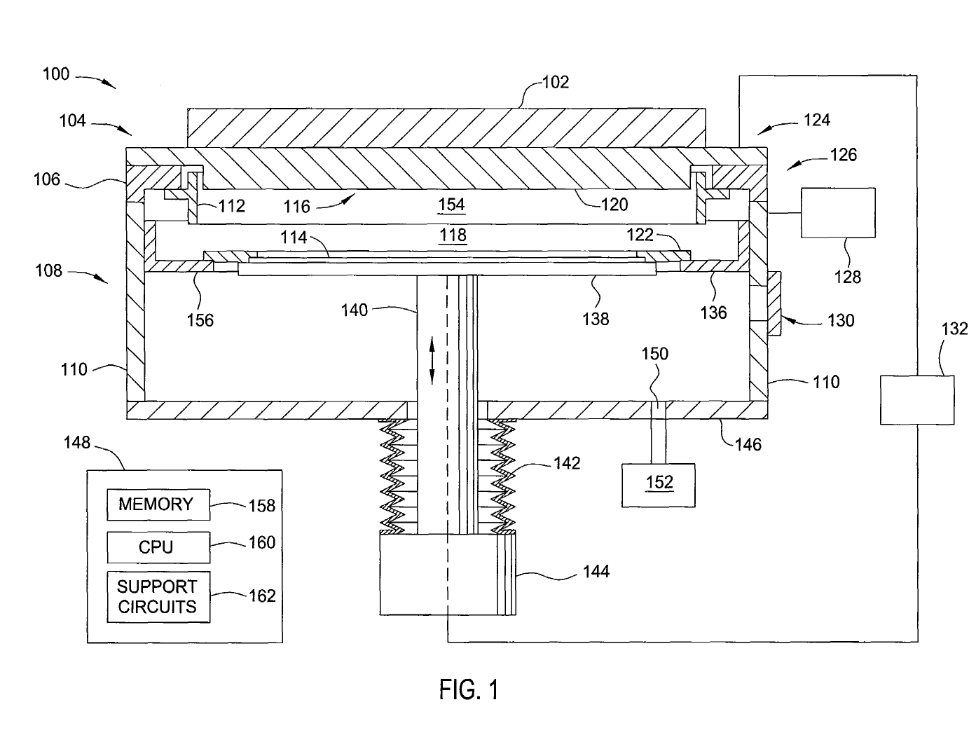

FIG. 1 illustrates an exemplary reactive sputter process chamber 100 suitable for sputter depositing materials according to one embodiment of the invention. One example of the process chamber that may be adapted to benefit from the invention is a PVD process chamber, available from Applied Materials, Inc., located in Santa Clara, Calif. It is contemplated that other sputter process chambers, including those from other manufactures, may be adapted to practice the present invention.

The process chamber 100 includes a chamber body 108 having a processing volume 118 defined therein. The chamber body 108 has sidewalls 110 and a bottom 146. The dimensions of the chamber body 108 and related components of the process chamber 100 are not limited and generally are proportionally larger than the size of the substrate 114 to be processed. Any suitable substrate size may be processed. Examples of suitable substrate sizes include substrate having a surface area of about 2000 centimeter square or more, such as about 4000 centimeter square or more, for example about 10000 centimeter square or more. In one embodiment, a substrate having a surface area of about 50000 centimeter square or more or more may be processed.

A chamber lid assembly 104 is mounted on the top of the chamber body 108. The chamber body 108 may be fabricated from aluminum or other suitable materials. A substrate access port 130 is formed through the sidewall 110 of the chamber body 108, facilitating the transfer of a substrate 114 (i.e., a solar panel, a flat panel display substrate, a semiconductor wafer, or other workpiece) into and out of the process chamber 100. The access port 130 may be coupled to a transfer chamber and/or other chambers of a substrate processing system.

A gas source 128 is coupled to the chamber body 108 to supply process gases into the processing volume 118. In one embodiment, process gases may include inert gases, non-reactive gases, and reactive gases. Examples of process gases that may be provided by the gas source 128 include, but not limited to, argon gas (Ar), helium (He), nitrogen gas (N₂), oxygen gas (O₂), and H₂O among others.

A pumping port 150 is formed through the bottom 146 of the chamber body 108. A pumping device 152 is coupled to the process volume 118 to evacuate and control the pressure therein. In one embodiment, the pressure level of the process chamber 100 may be maintained at about 1 Torr or less. In another embodiment, the pressure level of the process chamber 100 may be maintained at about 10⁻³ Torr or less. In yet another embodiment, the pressure level of the process chamber 100 may be maintained at about 10⁻⁵ Torr to about 10⁻⁷ Torr. In another embodiment, the pressure level of the process chamber 100 may be maintained at about 10⁻⁷ Torr or less.

The lid assembly 104 generally includes a target 120 and a ground shield assembly 126 coupled thereto. The target 120 provides a material source that can be sputtered and deposited onto the surface of the substrate 114 during a PVD process. The target 120 or target plate may be fabricated from a material utilized for deposition species. A high voltage power supply, such as a power source 132, is connected to the target 120 to facilitate sputtering materials from the target 120. In one embodiment, the target 120 may be fabricated from a material containing zinc (Zn) metal. In another embodiment, the target 120 may be fabricated by materials including metallic zinc (Zn) target, zinc alloy, zinc and aluminum alloy, zinc and gallium alloy, zinc containing ceramic oxide target, and the like.

The target 120 generally includes a peripheral portion 124 and a central portion 116. The peripheral portion 124 is disposed over the sidewalls 110 of the chamber. The central portion 116 of the target 120 may have a curvature surface slightly extending towards the surface of the substrate 114 disposed on a substrate support 138. The spacing between the target 120 and the substrate support 138 is maintained between about 50 mm and about 150 mm. It is noted that the dimension, shape, materials, configuration and diameter of the target 120 may be varied for specific process or substrate requirements. In one embodiment, the target 120 may further include a backing plate having a central portion bonded and/or fabricated by a material desired to be sputtered onto the substrate surface. The target 120 may also include adjacent tiles or segment materials that together forming the target.

Optionally, the lid assembly 104 may further comprise a magnetron assembly 102 mounted above the target 120 which enhances efficient sputtering materials from the target 120 during processing. Examples of the magnetron assembly include a linear magnetron, a serpentine magnetron, a spiral magnetron, a double-digitated magnetron, a rectangularized spiral magnetron, among others.

The ground shield assembly 126 of the lid assembly 104 includes a ground frame 106 and a ground shield 112. The ground shield assembly 126 may also include other chamber shield member, target shield member, dark space shield, dark space shield frame. The ground shield 112 is coupled to the peripheral portion 124 by the ground frame 106 defining an upper processing region 154 below the central portion of the target 120 in the process volume 118. The ground frame 106 electrically insulates the ground shield 112 from the target 120 while providing a ground path to the chamber body 108 of the process chamber 100 through the sidewalls 110. The ground shield 112 constrains plasma generated during processing within the upper processing region 154 and dislodges target source material from the confined central portion 116 of the target 120, thereby allowing the dislodged target source to be mainly deposited on the substrate surface rather than chamber sidewalls 110. In one embodiment, the ground shield 112 may be formed by one or more work-piece fragments and/or a number of these pieces bonding by processes known in the art, such as welding, gluing, high pressure compression, etc.

A shaft 140 extending through the bottom 146 of the chamber body 108 couples to a lift mechanism 144. The lift mechanism 144 is configured to move the substrate support 138 between a lower transfer position and an upper processing position. A bellows 142 circumscribes the shaft 140 and coupled to the substrate support 138 to provide a flexible seal therebetween, thereby maintaining vacuum integrity of the chamber processing volume 118.

A shadow frame 122 is disposed on the periphery region of the substrate support 138 and is configured to confine deposition of source material sputtered from the target 120 to a desired portion of the substrate surface. A chamber shield 136 may be disposed on the inner wall of the chamber body 108 and have a lip 156 extending inward to the processing volume 118 configured to support the shadow frame 122 disposed around the substrate support 138. As the substrate support 138 is raised to the upper position for processing, an outer edge of the substrate 114 disposed on the substrate support 138 is engaged by the shadow frame 122 and the shadow frame 122 is lifted up and spaced away from the chamber shield 136. When the substrate support 138 is lowered to the transfer position adjacent to the substrate transfer port 130, the shadow frame 112 is set back on the chamber shield 136. Lift pins (not shown) are selectively moved through the substrate support 138 to list the substrate 114 above the substrate support 138 to facilitate access to the substrate 114 by a transfer robot or other suitable transfer mechanism.

A controller 148 is coupled to the process chamber 100. The controller 148 includes a central processing unit (CPU) 160, a memory 158, and support circuits 162. The controller 148 is utilized to control the process sequence, regulating the gas flows from the gas source 128 into the chamber 100 and controlling ion bombardment of the target 120. The CPU 160 may be of any form of a general purpose computer processor that can be used in an industrial setting. The software routines can be stored in the memory 158, such as random access memory, read only memory, floppy or hard disk drive, or other form of digital storage. The support circuits 162 are conventionally coupled to the CPU 160 and may comprise cache, clock circuits, input/output subsystems, power supplies, and the like. The software routines, when executed by the CPU 160, transform the CPU into a specific purpose computer (controller) 148 that controls the process chamber 100 such that the processes are performed in accordance with the present invention. The software routines may also be stored and/or executed by a second controller (not shown) that is located remotely from the chamber 100.

During processing, the material is sputtered from the target 120 and deposited on the surface of the substrate 114. The target 120 and the substrate support 138 are biased relative to each other by the power source 132 to maintain a plasma formed from the process gases supplied by the gas source 128. The ions from the plasma are accelerated toward and strike the target 120, causing target material to be dislodged from the target 120. The dislodged target material and process gases forms a layer on the substrate 114 with desired compositions.

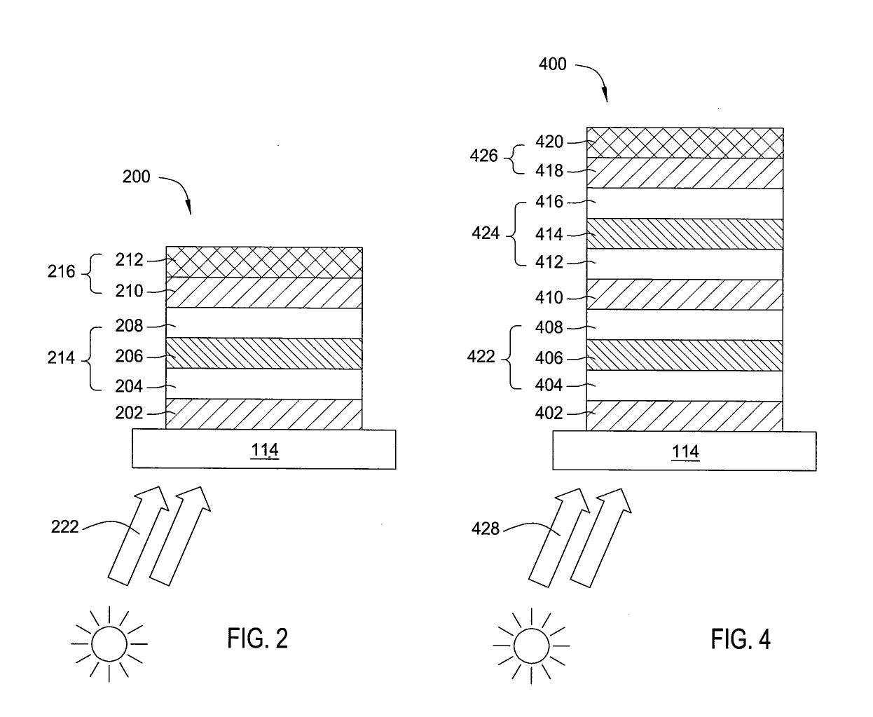

FIG. 2 depicts an exemplary cross sectional view of an amorphous silicon-based thin film PV solar cell 200 in accordance with one embodiment of the present invention. The amorphous silicon-based thin film PV solar cell 200 includes a substrate 114. The substrate 114 may be thin sheet of metal, plastic, organic material, silicon, glass, quartz, or polymer, or other suitable material. The substrate 114 may have a surface area greater than about 1 square meters, such as greater than about 2 square meters. Alternatively, the thin film PV solar cell 200 may also be fabricated as crystalline, microcrystalline or other type of silicon-based thin films as needed.

A photoelectric conversion unit 214 is formed on a TCO layer 202 disposed on the substrate 114. The photoelectric conversion unit 214 includes a p-type semiconductor layer 204, a n-type semiconductor layer 208, and an intrinsic type (i-type) semiconductor layer 206 sandwiched therebetween as a photoelectric conversion layer. An optional dielectric layer (not shown) may be disposed between the substrate 114 and the TCO layer 202. In one embodiment, the optional dielectric layer may be a SiON or silicon oxide (SiO₂) layer.

The p-type and n-type semiconductor layers 204, 208 may be silicon based materials doped by an element selected either from group III or V. A group III element doped silicon film is referred to as a p-type silicon film, while a group V element doped silicon film is referred to as a n-type silicon film. In one embodiment, the n-type semiconductor layer 208 may be a phosphorus doped silicon film and the p-type semiconductor layer 204 may be a boron doped silicon film. The doped silicon films 204, 208 include an amorphous silicon film (a-Si), a polycrystalline film (poly-Si), and a microcrystalline film (μc-Si) with a thickness between around 5 nm and about 50 nm. Alternatively, the doped element in semiconductor layers 204, 208 may be selected to meet device requirements of the PV solar cell 200. The n-type and p-type semiconductor layers 204, 208 may be deposited by a CVD process or other suitable deposition process.

The i-type semiconductor layer 206 is a non-doped type silicon based film. The i-type semiconductor layer 206 may be deposited under process condition controlled to provide film properties having improved photoelectric conversion efficiency. In one embodiment, the i-type semiconductor layer 206 may be fabricated by i-type polycrystalline silicon (poly-Si), i-type microcrystalline silicon film (μc-Si), amorphous silicon (a-Si), or hydrogenated amorphous silicon (a-Si).

After the photoelectric conversion unit 214 is formed on the TCO layer 202, a back reflector 216 is disposed on the photoelectric conversion unit 214. In one embodiment, the back reflector 216 may be formed by a stacked film that includes a transmitting conducting oxide (TCO) layer 210 and a conductive layer 212. The conductive layer 212 may be at least one of Ti, Cr, Al, Ag, Au, Cu, Pt, or their alloys. The transmitting conducting oxide (TCO) layer 210 may be fabricated from a material similar to the TCO layer 202 formed on the substrate 114. The transmitting conducting oxide (TCO) layers 202, 210 may be fabricated from a selected group consisting of tin oxide (SnO₂), indium tin oxide (ITO), zinc oxide (ZnO), or combinations thereof.

In embodiments depicted in FIG. 2, at least one of the transmitting conducting oxide (TCO) layers 202, 210 is fabricated by reactive sputter deposition according to the present invention. The sputter deposition process of TCO layers 202, 210 may be performed in the processing chamber 100, as described in FIG. 1.

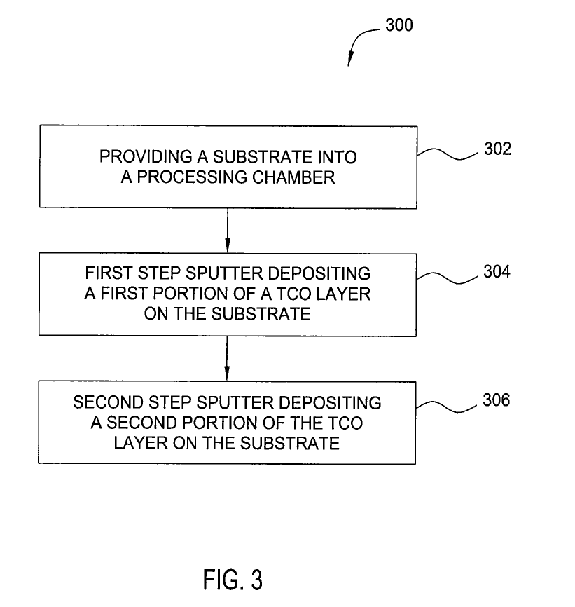

FIG. 3 depicts a flow diagram of one embodiment of a sputtering deposition process 300 for depositing a TCO layer, such as TCO layers 202, 210, on the substrate 114 or on the photoelectric conversion unit 214. The process 300 may be stored in the memory 158 as instructions that when executed by the controller 148, cause the process 300 to be performed in the process chamber 100. In embodiment depicted in FIG. 3, the process 300 is performed in an Thin Film Solar PECVE system from Applied Materials, Inc.

The process 300 begins at step 302 by providing a substrate into a sputter process chamber for deposition a TCO layer on the substrate. In one embodiment, the TCO layer may be deposited as the TCO layer 202 on the substrate 114. In another embodiment, the TCO layer may be deposited as the TCO layer on the photoelectric conversion unit 214 as the back reflector 216.

At step 304, a first step sputter deposition process is performed to sputter deposit a portion of the TCO layer. The first step sputter deposition process may be configured to deposit a portion of the TCO layer having different film properties than a second portion of the TCO layer deposited using a second sputtering deposition process further described below. As TCO layers may require different film property requirements in accordance with the different layers formed in the solar cell 200, the sputter deposition parameters may be varied to produce different compound film components and qualities. For example, the bottom TCO layer 202 may require film properties, such as relatively high textured surface, high transparency, and high conductivity as compared to the upper TCO layer 210. High textured surface facilitates incident light 222 transmitting through the substrate 114 to become trapped in the bottom TCO layer 202, thereby maximizing the light transmittance efficiency. Although the upper TCO layer 210 may require high transparency as well, however, the requirement for surface texturing is much less than that of the bottom TCO layer 202. In embodiments where the sputter depositing process as described in process 300 is utilized to form an upper TCO layer 210 as a back reflector, relatively low textured surface, high transparency, and high conductivity at the interface in contact with the photoelectric conversion unit 214 are desired.

During first step sputtering, a gas mixture may be supplied into the process chamber 100 to react with the source material sputtered from the target 120. In one embodiment, the gas mixture may include reactive gas, non-reactive gas, inert gas, and the like. Examples of reactive and non-reactive gas include, but not limited to, O₂, N₂, N₂O, NO₂, and NH₃, H₂O, among others. Examples of inert gas include, but not limited to, Ar, He, Xe, and Kr, among others.

In the embodiment depicted in FIG. 2, a metal alloy target made of Zinc (Zn) and aluminum (Al) metal alloy is utilized as a source material of the target 120 for sputter process. The ratio of Al metal included in the Zn and Al metal alloy target 120 is controlled at between about 0.5 percent by weight to about 5 percent by weight. As a high voltage power is supplied to the metal Zn target 120, the metal zinc source material is sputtered from the target 120 in form of zinc ions, such as Zn⁺ or Zn²⁺. The bias power applied between the target 120 and the substrate support 138 maintains a plasma formed from the gas mixture in the process chamber 100. The ions mainly from the inert gas or gas mixture in the plasma bombard and sputter off material from the target 120. The reactive gases react with the growing sputtered film to form a layer with desired composition on the substrate 114. The gas mixture and/or other process parameters may be varied during the sputtering deposition process, thereby creating a gradient with desired film properties for different film quality requirements.

In one embodiment, the gas mixture supplied into the processing chamber 100 includes O₂, Ar gas, or the combination thereof. The O₂ gas may be supplied at a flow rate between about 0 sccm and about 1000 sccm, such as between about 10 sccm and about 200 sccm, for example between about 15 sccm and about 100 sccm. Alternatively, O₂ gas flow may be controlled at a flow rate per chamber volume between about 0 sccm per chamber volume (liter) and about 29 sccm per chamber volume (liter), such as between about 0.28 sccm per chamber volume (liter) and about 6 sccm per chamber volume (liter), for example between about 0.43 sccm per chamber volume (liter) and about 2.89 sccm per chamber volume (liter). The Ar gas may be supplied into the processing chamber 100 at a flow rate between about 100 sccm and between 500 sccm, such as between about 100 sccm and about 250 sccm. Alternatively, Ar gas flow may be controlled at a flow rate per chamber volume between about 2.89 sccm per chamber volume (liter) and about 14.46 sccm per chamber volume (liter), such as between about 2.89 sccm per chamber volume (liter) and about 7.23 sccm per chamber volume (liter).

The oxygen ions dissociated from the O₂ gas mixture reacts with the zinc ions sputtered from the target, forming a zinc oxide (ZnO) layer as a first portion of the TCO layer 202 or 210 on the substrate 114. RF power is applied to the target 120 during processing. In one embodiment, the RF power density may be supplied between about 100 milliWatts per centimeter square and about 10000 milliWatts per centimeter square, such as between about 500 milliWatts per centimeter square and about 5000 milliWatts per centimeter square, for example, about 1000 milliWatts per centimeter square and about 4500 milliWatts per centimeter square. Alternatively, the DC power may be supplied between about 1000 milliWatts per centimeter square and about 30000 milliWatts per centimeter square, such as between about 500 milliWatts per centimeter square and about 1500 milliWatts per centimeter square, for example, about 1000 milliWatts per centimeter square and about 4500 milliWatts per centimeter square.

Several process parameters may be regulated at step 304. In one embodiment, a pressure of the gas mixture in the process chamber 100 is regulated between about 0 mTorr and about 100 mTorr, such as between about 1 mTorr and about 10 mTorr. The substrate temperature may be maintained between about 25 degrees Celsius and about 400 degrees Celsius, such as between about 150 degrees Celsius and about 250 degrees Celsius. The processing time may be processed at a predetermined processing period or after a desired thickness of the layer is deposited on the substrate. In one embodiment, the process time may be processed at between about 15 seconds and about 1200 seconds, such as between about 120 seconds to about 400 seconds. In another embodiment, the process time may be processed and terminated as the thickness of the first portion of the TCO layer has reached. In one embodiment, the thickness of the first portion of the TCO layer is between about 50 Å and about 8000 Å. In embodiment where the first sputtering step 304 is utilized to deposit a first portion of the top TCO layer 210, the thickness of the first portion of the top TCO layer 210 is deposited at between about 100 Å and about 800 Å. In embodiment where the first sputtering step 304 is utilized to deposit a first portion of the bottom TCO layer 202, the thickness of the first portion of the bottom TCO layer 202 is deposited at between about 1000 Å and about 8000 Å. In embodiment where a substrate with different dimension is desired to be processed, process temperature, pressure and spacing configured in a process chamber with different dimension do not change in accordance with a change in substrate and/or chamber size.

Alternatively, during first step sputtering, the gas mixture supplied into the processing chamber 100 may be varied during deposition of the TCO layer to create a gradient layer of properties within the layer. The power applied to sputter source material from the target 120 may be varied as well. In one embodiment, the gas mixture supplied into the processing chamber 100 may be increased or reduced between about 100 sccm and about 500 sccm per second until a desired gas flow rate is reached. Similarly, the power applied to the target 120 may be increased or reduced between 1000 Watts and about 10000 Watts per second until a desired processing power is achieved.

In an embodiment where the sputtering process is utilized to deposit the upper TCO layer 210 as a back reflector in the solar cell 200, the first step of deposition is configured to deposit a first portion of the TCO layer 210 having high conductivity and transparency and less textured surface. For example, as the first portion of the TCO layer 210 is directly in contact with the photoelectric conversion unit 214, the interfacial layer of the TCO layer 210 is desired to have high conductivity, such as having higher ratio of metal elements, to reduce contact resistance, thereby rendering a high electric conversion efficiency. In one embodiment, the contact resistivity of the first interfacial portion of the TCO layer 210 is less than about 1×E⁻² Ohm-cm, such as between about 1×E⁻² Ohm-cm and about 1×E⁻⁴ Ohm-cm. In embodiment where high conductivity of interfacial layer is desired, the O₂ gas mixture may be supplied at a relatively lower amount, such as at a lower gas flow rate, to create the sputter deposited film having high ratio of metal Zn relative to oxygen. Alternatively, a high voltage of power may be applied to the target 120 to sputter a relatively higher amount of Zn to create the desired film with high ratio of Zn element relative to oxygen element. As the upper TCO layer 210 is formed on the photoelectric conversion unit 214, the process temperature for sputter depositing the upper TCO layer 210 may be controlled at a relative low temperature, such as lower than 300 degrees Celsius, to prevent grain structure damage or other associated thermal damage of silicon film of the photoelectric conversion unit 214. In one embodiment, the process temperature for sputter depositing the upper TCO layer 210 may be controlled at between about 100 degrees Celsius and about 300 degrees Celsius, such as less than about 250 degrees Celsius.

In contrast, as for TCO layer deposited as the bottom TCO layer 202, a relatively high textured surface, high film conductivity and high film transparency may be desired. As the bottom TCO layer 202 is directly deposited on the substrate 114, a relatively higher process temperature for sputter depositing the bottom TCO layer 202 may be used as long as the substrate 114 is not adversely thermal damaged. For example, where the material of the substrate 114 is glass or ceramic material having a melting point higher than about 450 degrees Celsius, a higher process temperature range, such as higher than about 300 degrees Celsius and lower than about 450 degrees Celsius, may be used to produce a high transparency film. As the TCO layer deposited at a relatively higher process temperature may have a higher bulk film conductivity, the bottom TCO layer 202 that may be deposited at a higher temperature rather than the upper TCO layer 210 process temperature may have a higher bulk film conductivity than that of the upper bulk TCO layer 210. In one embodiment, the bottom TCO layer 202 may have a conductivity of about 1E⁻⁴ Ohm-cm higher than the conductivity of upper TCO layer 210.

At step 306, a second step sputter deposition process is performed to sputter deposit the TCO layer until a desired thickness of the second portion of the TCO layer or overall thickness of the TCO layer is reached. The process parameters and gas mixtures supplied into the processing chamber 100 at the second step 306 may be different from the first step 304 so that the second portion of the deposited TCO layers will have different film properties than the first portion.

During second step sputtering deposition at step 306, the first gas mixture and the flow rate of the first gas mixture supplied at step 304 may be smoothly transition into a second gas mixture and gas flow rate. The change in gas mixture and/or gas flow rate provides a different ratio of metal and oxygen during reaction, thereby resulting in the second portion of the TCO film having a different ratio of zinc metal and oxygen relative to that of the first portion. Additionally, the power applied at step 304 may be different from the power applied at step 306 to adjust of amount of metal sputtered during processing.

In embodiment where the second sputtering deposition process is utilized to deposit the upper second portion of the top TCO layer 210 for use as a back reflector, a high amount and/or flow rate of the gas mixture may be supplied into the processing chamber to cause the second portion of the TCO layer 210 to have a higher ratio of oxygen relative to metal Zn within the film. For example, a gas mixture having a higher oxygen gas flow at the second sputtering deposition process relative to the lower oxygen gas flow at the first sputtering deposition process at step 304 may be used to create a desired upper TCO layer 210 with two different film layers having two different film properties. The higher ratio of the oxygen to metal Zn allows the upper portion of the TCO layer 210 have a high transmittance without adversely affecting the overall conductivity and the contact resistance of the TCO layer 210. In embodiments where the second sputter deposition process is utilized to deposit the upper second portion of bottom TCO layer 202, a consistent high film transparency is desired to maximize the light transmitting efficiency. Accordingly, a high gas flow rate is utilized and desired to create the second upper portion of the bottom TCO layer 202 having a high ratio of oxygen relative to metal Zn. In one embodiment, the second portion of the bottom TCO layer 202 and/or upper TCO layer 210 has a higher working function than the first portion TCO layer 202 and/or upper TCO layer 210. For example, the second portion of the bottom TCO layer 202 and/or upper TCO layer 210 may have a working function about 0.3 eV higher than the second portion of the bottom TCO layer 202 and/or upper TCO layer 210.

In one embodiment, the gas mixture supplied into the processing chamber 100 includes O₂, Ar gas, or the combination thereof. The O₂ gas may be supplied at a flow rate between about 0 sccm and about 1000 sccm, such as between about 10 sccm and 300 sccm, for example between about 30 sccm and between 200 sccm, such as greater than 25 sccm. Alternatively, the O₂ gas may be controlled at a flow rate per chamber volume between about 0 sccm per chamber volume (liter) and about 28.9 sccm per chamber volume (liter), such as between about 0.289 sccm per chamber volume (liter) and about 8.68 sccm per chamber volume (liter), for example between about 0.86 sccm per chamber volume (liter) and between 5.78 sccm per chamber volume (liter), such as greater than 0.723 sccm per chamber volume (liter). The Ar gas may be supplied into the processing chamber 100 at a flow rate between about 100 sccm and about 500 sccm, such as between about 100 sccm and about 250 sccm. Alternatively, the Ar gas may be supplied into the processing chamber 100 at a flow rate per chamber volume between about 2.89 sccm per chamber volume (liter) and about 14.47 sccm per chamber volume (liter), such as between about 2.89 sccm per chamber volume (liter) and about 7.23 sccm per chamber volume (liter).

Alternatively, the O₂ gas utilized to sputter deposit the second portion of the TCO layer at step 306 may be supplied and regulated at a higher flow rate than the flow rate of the first portion of the TCO layer at step 304. In one embodiment, the O₂ gas flow rate supplied to sputter deposit at the second portion of the TCO layer may have a flow rate between about 10 sccm and 50 sccm, such as between about 0.289 sccm per chamber volume (liter) and about 1.45 sccm per chamber volume (liter), higher than the flow rate of the first portion of the TCO layer. In another embodiment, the O₂ gas flow rate supplied to sputter deposit at the second portion of the TCO layer may be controlled at a higher gas flow rate between about 30 sccm and 150 sccm, such as 0.868 sccm per chamber volume (liter) and about 4.34 sccm per chamber volume (liter), and the O₂ gas flow rate of the first portion of the top TCO layer 210 at step 304 at a lower flow rate between about 5 sccm and between 80 sccm, such as 0.145 sccm per chamber volume (liter) and about 2.314 sccm per chamber volume (liter). The oxygen ions dissociated from the O₂ gas mixture reacts with the zinc ions sputtered from the target, forming a zinc oxide (ZnO) layer as the TCO layer 202 or 210 on the substrate 114. A RF power is applied to the target 120 to excite the process gases. In one embodiment, the RF power density may be supplied between about 100 milliWatts per centimeter square and about 10000 milliWatts per centimeter square, such as between about 500 milliWatts per centimeter square and about 5000 milliWatts per centimeter square, for example, about 1000 milliWatts per centimeter square and about milliWatts per centimeter square. Alternatively, the DC power may be supplied between about 1000 Watts and about 30000 Watts, such as between about 500 milliWatts per centimeter square and about 1500 milliWatts per centimeter square, for example, about 1000 milliWatts per centimeter square and about 4500 milliWatts per centimeter square.

Several process parameters may be regulated at step 304. In one embodiment, a pressure of the gas mixture in the process chamber 100 is regulated between about 0 mTorr and about 100 mTorr, such as between about 1 mTorr and about 10 mTorr. The substrate temperature may be maintained between about 25 degrees Celsius and about 400 degrees Celsius, such as between about 150 degrees Celsius and about 250 degrees Celsius. The processing time may be processed at a predetermined processing period or after a desired thickness of the layer is deposited on the substrate. In one embodiment, the process time may be processed at between about 15 seconds and about 1200 seconds, such as between about 120 seconds to about 300 seconds. In another embodiment, the process time may be processed and terminated as the thickness of the TCO layer has reached to between about 50 Å and about 4000 Å. In embodiment where the second sputtering step 306 is utilized to deposit a second portion of the top TCO layer 210, the thickness of the second portion of the top TCO layer 210 is deposited at between about 100 Å and about 500 Å. In embodiment where the second sputtering step 306 is utilized to deposit a second portion of the bottom TCO layer 202, the thickness of the second portion of the bottom TCO layer 202 is deposited at between about 250 Å and about 5000 Å. The overall thickness, e.g., including the first portion deposited at step 304 and the second portion deposited at step 306, may be controlled at between about 400 Å and about 1500 Å for the top TCO layer 210 and at between about 6000 Å and about 1.3 μm for the bottom TCO layer 202.

Alternatively, during second sputtering step 306, the gas mixture supplied into the processing chamber 100 may be varied to sputter deposit the second portion of the TCO layer with a gradient of properties. The power applied to sputter source material from the target 120 may be varied as well. In one embodiment, the gas mixture supplied into the processing chamber 100 may be increased or reduced between about 100 sccm and about 500 sccm per second until a desired gas flow rate is reached. Similarly, the power applied to the target 120 may be increased or reduced between 1000 Watts and about 10000 Watts per second until a desired predetermined processing power is achieved.

In one embodiment, the TCO layers 202, 210 as depicted according to the present invention have a sheet resistance between about 1500 Ohm per square and about 2500 Ohm per square, such as about 2000 Ohm per square. The TCO layers have transmittance greater than about 85 percent measured by light having a wavelength between about 400 nm and about 1100 nm and film roughness less than about 100 Å.

In an exemplary embodiment, the O₂ gas flow rate supplied at the first step 304 is controlled between about 18 sccm and about 22 sccm, such as between about 0.52 sccm per chamber volume (liter) and about 0.636 sccm per chamber volume (liter) and the O₂ gas flow rate supplied at the second step 306 is controlled greater than about 25 sccm, such as 0.723 sccm per chamber volume (liter). The RF power density is supplied about 1000 milliWatts per centimeter square and the chamber pressure is maintained between about 4 mTorr.

In an exemplary embodiment, the O₂ gas flow rate supplied at the first step 304 is controlled at between about 35 sccm and about 40 sccm, such as between about 1.012 sccm per chamber volume (liter) and about 1.157 sccm per chamber volume (liter), and the O₂ gas flow rate supplied at the second step 306 is controlled greater than about 50 sccm, such as about 1.446 sccm per chamber volume (liter). The RF power density is supplied about 2000 milliWatts per centimeter square and the chamber pressure is maintained between about 6 mTorr.

In yet another exemplary embodiment, the O₂ gas flow rate supplied at the first step 304 is controlled at between about 80 sccm and about 90 sccm, such as between about 2.315 sccm per chamber volume (liter) and about 2.6 sccm per chamber volume (liter) and the O₂ gas flow rate supplied at the second step 306 is controlled greater than about 100 sccm, such as about 2.89 sccm per chamber volume (liter). The RF power density is supplied about 4000 milliWatts per centimeter square and the chamber pressure is maintained between about 7 mTorr.

In operation, the incident light 222 provided by the environment is supplied to the PV solar cell 200. The photoelectric conversion unit 214 in the PV solar cell 200 absorbs the light energy and converts the light energy into electrical energy by operation of the p-i-n junctions formed in the photoelectric conversion unit 214, thereby generating electricity or energy. Alternatively, the PV solar cell 200 may be fabricated or deposited in a reversed order. For example, the substrate 114 may be disposed over the back reflector 216.

FIG. 4 depicts an exemplary cross sectional view of a tandem type PV solar cell 400 fabricated in accordance with another embodiment of the present invention. Tandem type PV solar cell 400 has a similar structure of the PV solar cell 200 including a bottom TCO layer 402 formed on the substrate 114 and a first photoelectric conversion unit 422 formed on the TCO layer 402. The first photoelectric conversion unit 422 may be μc-Si based, poly-silicon or amorphous based photoelectric conversion unit as the photoelectric conversion unit 214 described in FIG. 2. An intermediate layer 410 may be formed between the first photoelectric conversion unit 422 and a second photoelectric conversion unit 424. The intermediate layer 410 may be a TCO layer sputter deposited by the process 300 described above. The combination of the first underlying conversion unit 422 and the second photoelectric conversion unit 424 as depicted in FIG. 4 increases the overall photoelectric conversion efficiency.

The second photoelectric conversion unit 424 may be an μc-Si based, poly-silicon or amorphous based and have an μc-Si film as the i-type semiconductor layer 414 sandwiched between a p-type semiconductor layer 412 and a n-type semiconductor layer 416. A back reflector 426 is disposed on the second photoelectric conversion unit 424. The back reflector 426 may be similar to back reflector 216 as described with reference to FIG. 2. The back reflector 426 may comprise a conductive layer 420 formed on a top TCO layer 418. The materials of the conductive layer 420 and the TCO layer 418 may be similar to the conductive layer 212 and TCO layer 210 as described with reference to FIG. 2.

The intermediate TCO layer 410 may be deposited in a manner having predetermined film properties. For example, the intermediate TCO layer 410 may require having relatively even surface, high transmittance, high conductivity and low contact resistance on both the upper contact surface to the second photoelectric conversion unit 424 and the lower contact surface to the first photoelectric conversion unit 422. In one embodiment, the intermediate TCO layer 410 may be deposited by the two step sputter deposition process described above. The TCO layer 410 may be formed by adjusting the flow rate and gas components of the gas mixture during sputter depositing to create a desired ratio between the metal and oxygen in the film.

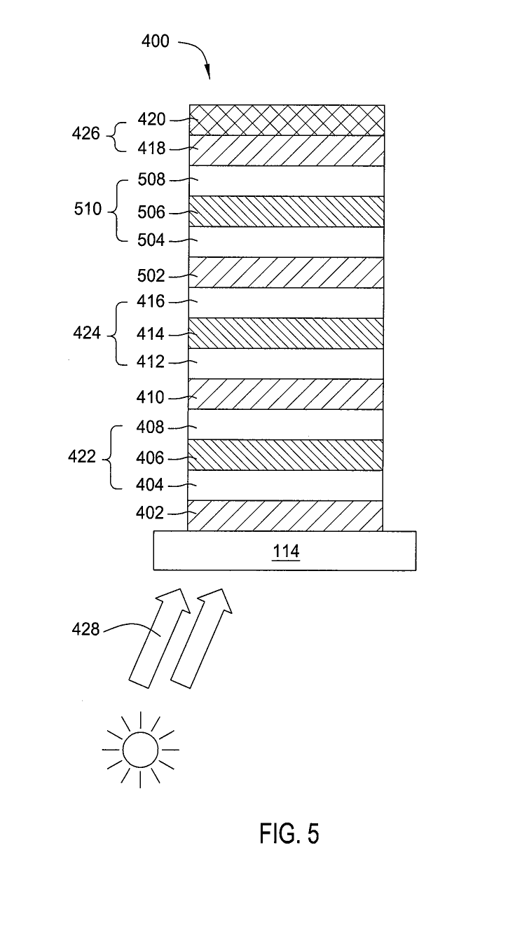

Alternatively, a third overlying photoelectric conversion unit 510 may be formed on the second photoelectric conversion unit 424, as shown in FIG. 5. An intermediate layer 502 may be disposed between the second photoelectric conversion unit 424 and the third photoelectric conversion unit 510. The intermediate layer 502 may be a TCO layer similar to the intermediate TCO layer of 410 described with reference to FIG. 4. The third photoelectric conversion unit 510 may be substantially similar to the second photoelectric conversion unit 424 having an i-type semiconductor layer 506 disposed between a p-type semiconductor layer 504 and a n-type layer 508. The third photoelectric conversion unit 510 may be a μc-Si-type photoelectric conversion unit having an i-type semiconductor layer 506 formed by an μc-Si film. Alternatively, the i-type semiconductor layer 506 may be formed by a poly-Si or an amorphous silicon layer. The p-type 504 and n-type semiconductor layer 508 may be a-Si layer. It should be noted that one or more photoelectric conversion units may optionally deposited on the third photoelectric conversion unit utilized to promote photoelectric conversion efficiency.

Although the process method 300 is described as two step sputter depositing process, it is noted that multiple sputter deposition steps may also be utilized to perform the present invention. In some embodiments where the deposited film are required to have an unitary and consistent single film structure and component, the process conditions and/or parameters at the second sputter deposition step may be substantially similar as the process conditions and/or parameter used in the first sputter depositing step, rendering the overall film properties similar to those obtained using a single step sputter process.

Thus, methods for sputtering depositing a TCO layer are provided. The method advantageously produces a TCO layer having different film properties across its thickness. In this manner, the TCO layers efficiently increase the photoelectric conversion efficiency and device performance of the PV solar cell as compared to conventional methods.

While the foregoing is directed to embodiments of the present invention, other and further embodiments of the invention may be devised without departing from the basic scope thereof, and the scope thereof is determined by the claims that follow.

What is claimed is:

1. A method of sputter depositing a transparent conductive oxide layer, comprising:
providing a substrate in a processing chamber;
forming a first portion of a transparent conductive oxide layer on the substrate by a first sputter deposition step; and
forming a second portion of the transparent conductive oxide layer by a second sputter deposition step.

2. The method of claim 1, wherein the step of forming the first portion of the transparent conductive oxide layer further comprises:
supplying a first gas mixture into the processing chamber;
sputtering source material from a target disposed in the processing chamber; and
reacting the sputtered material with the first gas mixture.

3. The method of claim 1, wherein the step of forming the second portion of the transparent conductive oxide layer further comprises:
supplying a second gas mixture into the processing chamber;
sputtering source material from the target; and
reacting the sputtered material with the second gas mixture.

4. The method of claim 2, wherein the step of supplying the first gas mixture further comprising:
supplying the first gas mixture selected from a group consisting of O₂, N₂O, N₂, Ar, He and H₂O.

5. The method of claim 2, wherein the first gas mixture includes O₂ and Ar.

6. The method of claim 2, wherein the target is fabricated from at least one of Zn, Zn alloy, Zn and Al alloy, Zn and Ga alloy and ceramic Zn oxide.

7. The method of claim 2, wherein the step of supplying the first gas mixture further comprises:
adjusting a flow rate of the first gas mixture during sputtering.

8. The method of claim 2, wherein the step of sputtering source material from the target further comprises:
applying a first power to the target.

9. The method of claim 8, wherein the step of applying the power further comprises:
adjusting the first power applied to the target during the first sputter deposition step.

10. The method of claim 5, further comprises:
supplying O₂ gas at a flow rate between about 0 sccm and about 1000 sccm; and
supplying Ar gas at a flow rate between about 100 sccm and about 500 sccm.

11. The method of claim 3, wherein the step of forming the second portion of the transparent conductive oxide layer further comprises:
supplying the second gas mixture selected from a group consisting of O₂, N₂O, N₂, Ar, He and H₂O.

12. The method of claim 3, wherein the second gas mixture includes O₂ and Ar.

13. The method of claim 3, wherein the step of supplying the second gas mixture further comprises:
adjusting a flow rate of the second gas mixture flow rate during sputtering.

14. The method of claim 3, wherein the step of sputtering source material from the target further comprises:
applying a second power to the target.

15. The method of claim 14, wherein the step of applying the second power further comprises:
adjusting the second power applied to the target during the second sputter deposition step.

16. The method of claim 1, wherein the first portion of the transparent conductive oxide layer has a thickness between about 50 Å and about 8000 Å and the second portion of the transparent conductive oxide layer has a thickness between about 50 Å and about 4000 Å.

17. The method of claim 14, wherein the process parameters of the first sputter deposition step are the same as the process parameters of the second sputter deposition step.

18. The method of claim 1, wherein the providing the substrate in a processing chamber further comprises:
controlling the substrate temperature at between about 25 degrees Celsius and about 400 degrees Celsius.

19. The method of claim 1, wherein the transparent conductive oxide layer is utilized as a back reflector in a photovoltaic device.

20. A method of sputter depositing a transparent conductive oxide layer, comprising:
providing a substrate in a processing chamber;
supplying a gas mixture into the processing chamber;
sputtering source material from a target disposed in the processing chamber to deposit a first portion of a transparent conductive oxide layer;
adjusting a flow rate of the gas mixture supplied to the processing chamber during sputtering; and
forming a second portion of the transparent conductive oxide layer on the substrate.

21. The method of claim 20, wherein the step of sputtering source material from the target further comprises:
adjusting a power applied to the target during sputtering.

22. The method of claim 20, wherein the transparent conductive oxide layer is a ZnO layer.

23. The method of claim 20, wherein the gas mixture is selected from a group consisting of O₂, N₂O, N₂, Ar, He and H₂O.

24. The method of claim 20, wherein the target is fabricated at least one of Zn, Zn alloy, Zn and Al alloy, Zn and Ga alloy, and ceramic oxide Zn.

25. A method of sputter depositing a transparent conductive oxide layer, comprising:
providing a substrate in a processing chamber;
supplying a first gas mixture into the processing chamber;
sputtering source material from a Zn containing target disposed in the processing chamber;
reacting the sputtered source material with the first gas mixture to form a first portion of a transparent conductive oxide layer on the substrate;
supplying a second gas mixture into the processing chamber and reacting with the sputtered source material; and
forming a second portion of the transparent conductive oxide layer on the substrate.

26. The method of claim 25, wherein the transparent conductive oxide layer is a ZnO layer.

27. The method of claim 25, further comprising:
adjusting the gas flow rate of the first and the second gas mixture during sputtering.

28. A method of sputter depositing a transparent conductive oxide layer, comprising:
providing a substrate in a processing chamber;
supplying a first gas mixture having oxygen gas into the processing chamber;
sputtering source material from a Zn containing target disposed in the processing chamber;
reacting the sputtered source material with the first gas mixture to form a first portion of a transparent conductive oxide layer on the substrate;
supplying a second gas mixture having oxygen gas into the processing chamber and reacting with the sputtered source material, wherein the oxygen gas flow in the second gas mixture is greater than the oxygen gas flow in the first gas mixture; and
forming a second portion of the transparent conductive oxide layer on the substrate.

29. The method of claim 28, wherein the second portion of the transparent conductive oxide layer has a higher transmittance than the first portion of the transparent conductive oxide layer.

30. The method of claim 28, wherein the step of sputtering source material further comprising:
adjusting a power supplied to the target.

31. The method of claim 30, wherein the power supplied to the target in the first gas mixture is lower than the power supplied in the second gas mixture.
